(19) United States
(12) Patent Application Publication
(10) Pub. No.: US 2008/0036044 A1
(43) Pub. Date: Feb. 14, 2008

(54) SEMICONDUCTOR OPTICAL DEVICE AND MANUFACTURING METHOD THEREFOR

(76) Inventors: Yasushi Sakuma, Tokyo (JP); Kazuhiro Komatsu, Yokohama (JP); Shigenori Hayakawa, Atsugi (JP); Daisuke Nakai, Yokohama (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/832,248

(22) Filed: Aug. 1, 2007

(30) Foreign Application Priority Data
Aug. 10, 2006 (JP) 2006-218341

(51) Int. Cl. H01L 29/06; H01L 21/302

(52) U.S. Cl. 257/622; 438/706; 257/E29.005; 257/E21.214

(57) ABSTRACT

To eliminate generation of a damaged layer caused by dry etching of a contact layer, occurring in a manufacturing process of a ridge waveguide type semiconductor laser, and to improve reliability and yield thereof, a method is provided involving forming a spacer layer and a damage receptor layer on the contact layer, making the two layer absorb damage caused by dry etching a passivation film in an upper portion of the ridge waveguide structure, and thereafter removing the damaged layer by the dry etching, by selective removal by wet etching.

This application claims a priority from the Japanese Patent Application No. 2006-218341 filed on Aug. 10, 2006, the entire content of which is incorporated by reference herein.

### FIELD OF THE INVENTION

The present invention relates to a semiconductor optical device and a manufacturing method therefor, and more particularly, to a technology which is effective when applied to a semiconductor laser device having a ridge waveguide structure.

### BACKGROUND OF THE INVENTION

In general, in a semiconductor laser device, to attain an enhanced efficiency of current injection and to a control lateral mode thereof, a ridge waveguide structure is formed between a contact layer and a second clad layer. This ridge waveguide structure is referred to as a semiconductor mesa, and laser oscillation can be performed by injecting current to the contact layer on the semiconductor mesa.

Hitherto, a process for forming a current injection region above the semiconductor mesa has involved removing a passivation film above the semiconductor mesa by wet etching using a fluorine-based etching solution. However, this process is inferior in precision of the etching depth control, so that a threshold value increase and a reliability degradation caused by passivation film defects at a bottom of the semiconductor mesa, or lowering of optical output caused by reductions in passivation film thicknesses in side walls of the semiconductor mesa occur, causing large deterioration in production yields.

To deal with this problem, a method is known involving etching the passivation film above the semiconductor mesa by dry etching such as reactive ion etching (RIE), which has superior precision in etching depth control.

However, the method using dry etching is also known to cause problems such as crystal surface roughness due to ion irradiation, contamination of hydrogen molecules generated from a reaction gas into a crystal (hydrogen passivate), and attachment of reaction products. In a case where a damaged layer or a reaction product due to the dry etching described above exist in an upper portion of the semiconductor mesa, since an increase in contact resistance or reliability defects occur, post-processing after dry etching becomes important.

Generally employed post-treatment of the dry etching includes a method involving first removing reaction products using oxygen plasma ashing and concentrated sulfuric acid immersion, followed by removing and anneal-treating hydrogen molecules contaminated into the crystal at about 600° C. Further, there is employed a removing method involving wet etching the damaged layer exposed to the dry etching.

### SUMMARY OF THE INVENTION

However, the following problems arise in cases where these methods are applied to post-treatment after dry etching of a passivation film located on an upper portion of a ridge waveguide structure.

First, in a method involving oxygen plasma ashing, thermal diffusion of a carrier from a second clad layer to an active layer occurs. This causes degradation of a laser property, which is not desirable as a post-treatment method.

Besides, by a removing method using wet etching, it is difficult to selectively remove only a damaged layer of several 10 nm in thickness by wet etching in a structure of an upper portion of a conventional ridge waveguide structure formed of two layers including a contact layer and a second clad layer, resulting in lower production yields.

On the other hand, there has been progress in developing dry etching devices such as an inductively coupled plasma (ICP) device capable of reducing damaged layers and reaction products themselves caused by the dry etching, and an electron cyclotron resonance-reactive ion etching device (ECR-RIE). However, it is difficult to reduce generation of these to zero, and there arises a problem due to cost increases with introduction of the devices.

Therefore, it is an object of the present invention to arrange so that there is no generation of a damaged layer caused by the dry etching within the contact layer in the ridge waveguide structure, and to provide a technology capable of improving reliability and yield of a semiconductor optical device.

To attain the above-mentioned object of the invention, the present invention adopts the following measures: two layers including a damage receptor layer and a spacer layer are laminated on a contact layer before dry etching of a passivation film in an upper portion of a ridge waveguide structure; damage of the passivation film caused by the dry etching is absorbed by the damage receptor layer and the spacer layer; and the damage receptor layer and the spacer layer are selectively removed by wet etching after the dry etching of the passivation film. As a result, the generation of the damaged layer caused by the dry etching may be prevented from occurring in the contact layer.

For example, according to the present invention, in a semiconductor optical device including a plurality of layers laminated on a semiconductor substrate, a groove is formed as deep as a predetermined first layer, among the plurality of layers, by dry etching and by wet etching after the dry etching; a spacer layer is formed on an upper surface of a second layer located on an upper surface of the plurality of layers; and a damage receptor layer is formed on an upper surface of the spacer layer.

The spacer layer is made of a material which can be selectively etched with respect to the second layer; the spacer layer is made of a material having a small selective ratio with respect to a third layer formed in contact with an upper surface of the first layer; and the damage receptor layer serves to prevent formation of the damaged layer in the second layer caused by the dry etching.

As described above, according to the present invention, the damaged layer above the ridge waveguide structure caused by the dry etching of the passivation film may be absorbed in the damage receptor layer. With this, it is possible to prevent the damaged layer from occurring in the contact layer. As a result, it is possible to form a current injection region on the ridge waveguide structure in a highly controllable state and a stable state. Specifically, it is possible to improve a basic property, reliability, and yields of the semiconductor optical device.

### BRIEF DESCRIPTION OF THE DRAWINGS

FIG. 1 is a cross-sectional view of a main part of a semiconductor substrate showing a manufacturing method of a ridge waveguide type semiconductor laser according to Embodiment 1 of the present invention;

FIG. 2 is a cross-sectional view of the main part of the semiconductor substrate showing the manufacturing method of the ridge waveguide type semiconductor laser according to Embodiment 1 of the present invention;

FIG. 3 is a cross-sectional view of the main part of the semiconductor substrate showing the manufacturing method of the ridge waveguide type semiconductor laser according to Embodiment 1 of the present invention;

FIG. 4 is a cross-sectional view of the main part of the semiconductor substrate showing the manufacturing method of the ridge waveguide type semiconductor laser according to Embodiment 1 of the present invention;

FIG. 5 is a cross-sectional view of the main part of the semiconductor substrate showing the manufacturing method of the ridge waveguide type semiconductor laser according to Embodiment 1 of the present invention;

FIG. 6 is a perspective view of the ridge waveguide type semiconductor laser according to Embodiment 1 of the present invention;

FIG. 7 is a perspective view of the ridge waveguide type semiconductor laser according to Embodiment 2 of the present invention; and

FIG. 8 is a perspective view of an EA modulator integrated semiconductor laser according to Embodiment 3 of the present invention.

### DETAILED DESCRIPTION OF THE EMBODIMENTS

Hereinafter, embodiments of the present invention will be described with reference to the drawings. First, descriptions will be made of structures of semiconductor optical devices according to embodiments of the present invention, and then manufacturing methods thereof will be described.

As shown in FIG. 6, a semiconductor optical device according to the present invention is an example applied to a semiconductor laser device of a ridge waveguide structure.

FIG. 6 shows a ridge waveguide type semiconductor laser according to the present invention. A buffer layer 2, a clad layer 3, a guide layer 4, a strained multiple quantum well active layer 5, a guide layer 6, a clad layer 7, a hetero barrier reducing layer 8, a contact layer 9, a spacer layer 10, and a damage receptor layer 11 are formed on a semiconductor substrate 1 in the stated order. Further, two grooves 100 are formed by engraving from an upper surface toward the semiconductor substrate 1 as deep as a location including the contact layer 9 and the clad layer 7 (as deep as an upper surface of the guide layer 6 in this embodiment). A ridge waveguide structure 200 is constructed by being sandwiched by those grooves 100 and 100. On the other hand, a region of an outer side of the stripe-like groove 100 constitutes a ridge protective layer 300.

Although not shown, the strained multiple quantum well active layer 5 is constructed by laminating plural well layers and barrier layers.

Formed on the contact layer 9 are the spacer layer 10 and the damage receptor layer 11. The spacer layer 10 is formed by a material which can be selectively etched with respect to the contact layer 9. The damage receptor layer 11 provides receiving and protecting functions so that ions irradiated at the time of the dry etching are prevented from entering into the contact layer 9. Specifically, the damage receptor layer 11 is formed by a material that is resistant to the dry etching so that the generation of the damaged layer occurs in the contact layer 9 caused by the dry etching.

Besides, on the upper surface of the ridge waveguide structure 200, the spacer layer 10 and the damage receptor layer 11 on the contact layer 9 are removed in the course of the manufacturing process. For that reason, the ridge waveguide structure 200 has a height lower than that of the upper surface of the ridge protective layer 300 by a thickness corresponding to the thickness sum of the spacer layer 10, the damage receptor layer 11, and the passivation film 13.

In the ridge waveguide structure 200, the contact layer 9 is not covered with the spacer layer 10, the damage receptor layer 11, and the passivation film 13, so that the contact layer 9 and the electrode 14 (in this case, p-type electrode) are in an electrically connected state.

In the ridge protective layer 300, the spacer layer 10 and the damage receptor layer 11 are provided on the contact layer 9. Those two layers are in a state covered with the passivation film 13.

Besides, an electrode 15 is formed on a backside of the semiconductor substrate 1. In this case, the electrode 15 is formed as an n-type electrode. In addition, formed on a peripheral cleavage plane of the semiconductor substrate 1 is a reflective protective film 16.

In the semiconductor optical device of this embodiment, the semiconductor substrate 1 side is an n-type and an opposite side is a p-type, with the strained multiple quantum well active layer 5 sandwiched therebetween. An example of a multi layer structure of the semiconductor optical device according to this embodiment is described.

The semiconductor optical device according to this embodiment has the multi layer structure, which is obtained by forming, on an n-type indium phosphide (InP) substrate 1, an n-type InP buffer layer 2 having a film thickness of 200 nm, an n-type InP clad layer 3 having a film thickness of 500 nm, an indium aluminum arsenide (InAlAs) layer 4 having a film thickness of 30 nm, an indium gallium aluminum arsenide (InGaAlAs) well layer having a film thickness of 5 nm, an InGaAlAs-based strained multiple quantum well active layer 5 formed of an InGaAlAs barrier layer having a film thickness of 8 nm, an InAlAs layer 6 having a film thickness of 30 nm, a p-type InP clad layer 7 having a film thickness of 1,600 nm, an indium gallium arsenide phosphide (InGaAsP) hetero barrier reducing layer 8 having a film thickness of 30 nm, a p-type indium gallium arsenide (InGaAs) contact layer 9 having a film thickness of 200 nm, anon-doped InP spacer layer 10 having a film thickness of 100 nm, and a non-doped InGaAs damage receptor layer 11 having a film thickness of 30 nm in the stated order.

Note that the indium aluminum arsenide (InAlAs) layer 4 may be formed of the indium gallium arsenide phosphide (InGaAsP). In this case, the InGaAlAs-based material is used for the strained multiple quantum well active layer 5, the InGaAsP-based materials may also be used. Further, to suppress the generation of reactive current, the non-doped InP spacer layer 10 is used. However, other high resistant material such as Fe dope InP may also used. Furthermore, the InGaAs is used for the damage receptor layer 11. However, the InGaAsP-based materials may also be used therefor.

The stripe-like grooves 100 are formed between the contact layer 9 and the p-type InP clad layer 7 of the laminate structure, and the center portion between the grooves 100 has the ridge waveguide (semiconductor mesa) structure 200. In addition, there is a feature in which the contact layer 9 in the upper portion of the ridge waveguide structure has no damage layer caused by the dry etching of the passivation film 13.

Next, a more specific structure of the semiconductor optical device according to Embodiment 1 of the present invention will be described in detail together with its manufacturing method, with reference to the drawings. Embodiment 1 is applied to a ridge waveguide type semiconductor laser device having an oscillation wavelength of 1.3 μm, and the manufacturing process thereof is as follows.

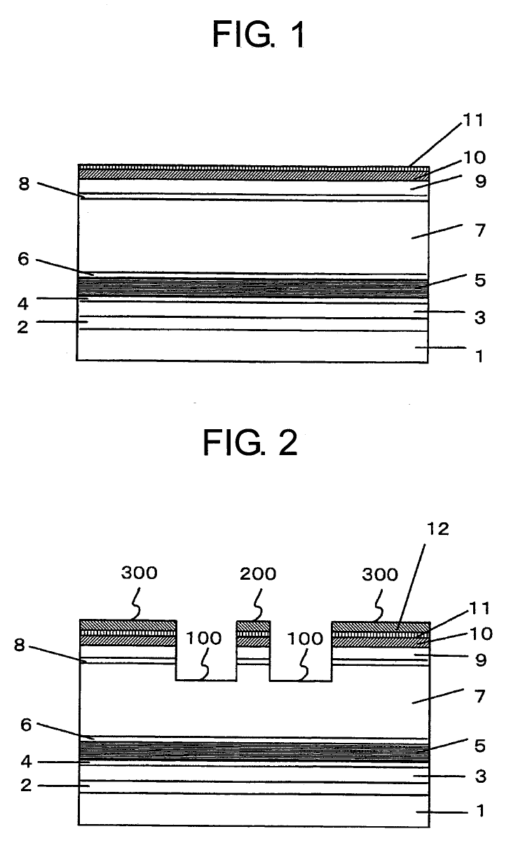

First, as shown in FIG. 1, a multi layer structure is formed in the above-mentioned order on an n-type indium phosphide (InP) substrate 1 by a metal organic chemical vapor deposition method (MOCVD method).

Next, as shown in FIG. 2, by using as a mask material a CVD oxide film 12 having a film thickness of 100 nm (hereinafter, referred to as SiO₂ film), dry etching is performed as far as a midway portion of the p-type InP clad layer 7, and processing is performed to obtain a structure having stripe-like grooves 100.

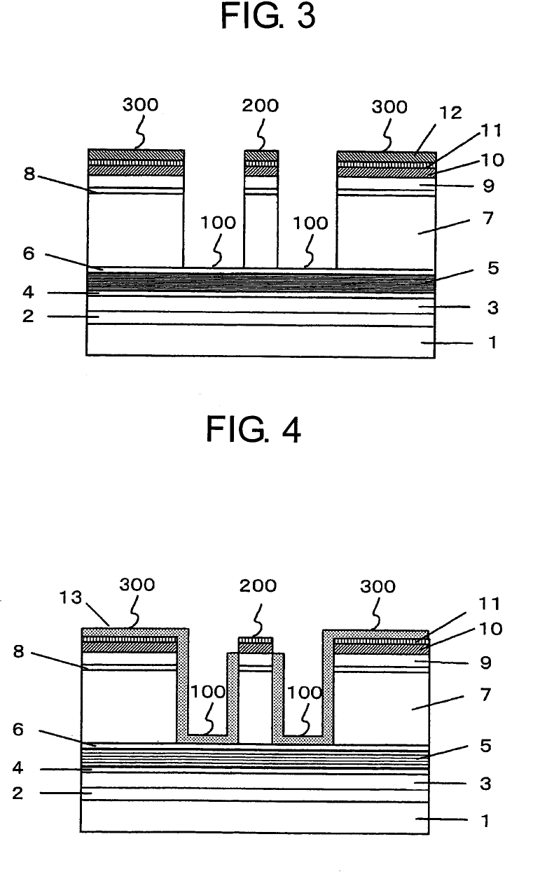

Subsequently, wet etching using a mixture solution of hydrochloric acid and phosphoric acid is performed to a p-type InP clad layer 7 to obtain the stripe like grooves 100. As a result, a ridge waveguide (semiconductor mesa) structure 200 shown in FIG. 3 is formed in the center of the multi layer structure, and the width thereof is 2.0 μm. The width of each of the stripe-like grooves 100 is 10 μm. Further, ridge protective layers 300 are formed on both sides of the stripe like structure 100.

In this case, a non-doped InP spacer layer 10 has an etched shape in accordance with a crystal orientation due to the existence of a non-doped InGaAs damage receptor layer 11, so dissipation of the film thickness caused by side etching does not occur.

Next, the stripe like SiO₂ film 12 is removed by wet etching. After that, a passivation film 13 of 500 nm thickness is formed on an entire substrate, by a CVD method. Then, by using photolithography and dry etching, the upper portion of the ridge waveguide structure, which becomes a current injection region, and the passivation film 13 of the side walls of the non-doped InP spacer layer 10 and the damage receptor layer 11 of the ridge waveguide structure, as shown in FIG. 4, are etched.

In this case, a damaged layer of several 10 nm thickness is formed on the surface of the non-doped InGaAs damage receptor layer 11 and the non-doped InP spacer layer 10 subjected to the dry etching process.

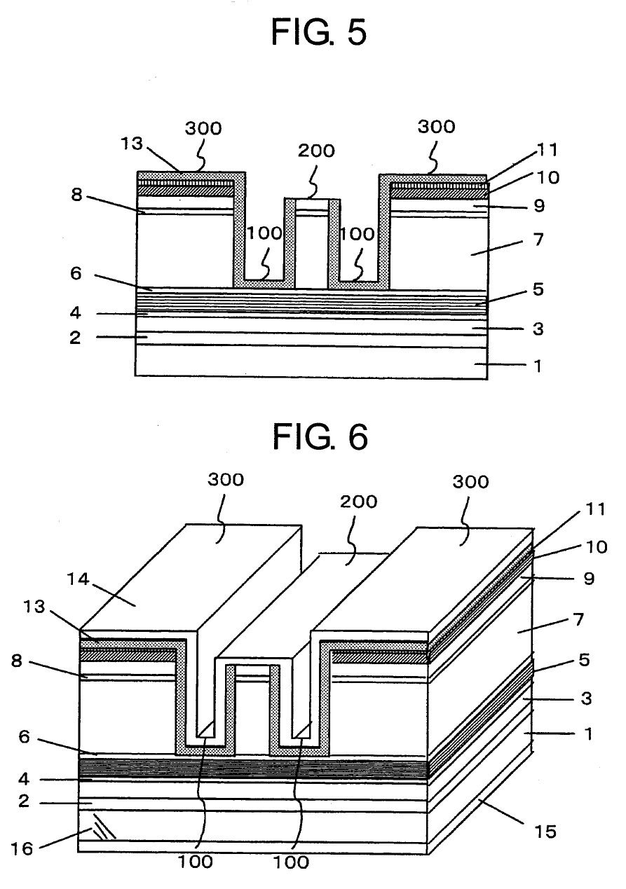

Next, as shown in FIG. 5, the damage receptor layer 11 and the spacer layer 10 including the damaged layer caused by the dry etching are removed, using as a mask material the passivation film 13 on the side walls of the ridge waveguide structure. In this case, first, the non-doped InGaAs damage receptor layer 11 is removed by wet etching using a mixture solution of phosphoric acid and hydrogen peroxide water. Next, the InP spacer layer 10 is removed by wet etching using a mixture solution of hydrochloric acid and phosphoric acid. By those processes, the contact layer 9 of the upper portion of the ridge waveguide structure (semiconductor mesa) 200 is exposed.

Next, as shown in FIG. 6, a p-side electrode 14 made of Ti/Pt/Au is formed into a film thickness of about 1 μm by an electron beam (EB: electron beam) deposition method. After that, this p-side electrode 14 is subjected to patterning by ion milling. Besides, the substrate surface is polished into a thickness of 100 μm to form an n-side electrode 15.

After that, an electrode alloying process or the like is performed. Then, a wafer is cleavaged into bars so that the length of the device becomes 200 μm. After forming a reflective protective film 16 on the cleavaged surface, the device is divided into chip shapes. Thus, a ridge waveguide type semiconductor laser having an oscillation wavelength of 1.3 μm band is completed.

As the result of current injection into the semiconductor laser manufactured by this embodiment, laser oscillation occurred at a threshold current of 12 mA, and an oscillation spectrum is observed at a wavelength of 1,301 nm.

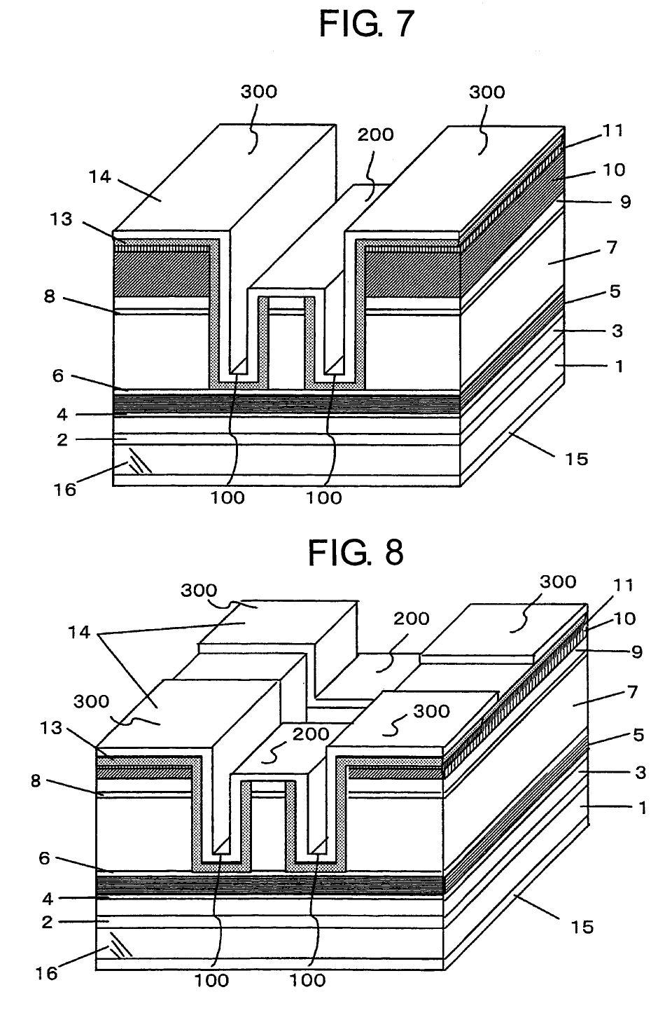

Next, Embodiment 2 of the present invention will be described with reference to FIG. 7. Embodiment 2, as well as Embodiment 1, is applied to a ridge waveguide type semiconductor laser device having an oscillation wavelength of 1.3 μm. However, Embodiment 2 is an example of a case in which a film thickness of the non-doped InP spacer layer 10 is thickened to 1,000 nm. The method of manufacturing a semiconductor laser according to Embodiment 2 is the same as that in Embodiment 1 described above.

In the above-mentioned device structure, the film thickness of the non-doped InP spacer layer 10 is thickened to 1,000 nm, so that the height of the ridge waveguide structure 200 is further lowered. As a result, a ridge protective layer 300, which becomes higher by the film thickness of the non-doped InP spacer layer 10, serves a role of protecting the ridge waveguide structure 200. For example, in a device fabricating process, it is possible to prevent the ridge waveguide structure 200 from being damaged. With this, it is possible to significantly reduce crystal defects, etc.

As the result of current injection into the semiconductor laser manufactured by this embodiment, laser oscillation occurred at a threshold current of 11 mA, and the oscillation spectrum is observed at a wavelength of 1,303 nm.

Note that the film thickness of the spacer layer may be changed within a range of from 100 nm to 3 μm.

Next, Embodiment 3 of the present invention will be described with reference to FIG. 8. Embodiment 3 is an example of a semiconductor laser in which semiconductor optical devices such as electro-absorption (EA) modulators or the like are integrated.

The semiconductor laser portion according to Embodiment 3 of the present invention can be manufactured by the same process as that of Embodiment 1 and Embodiment 2. FIG. 8 shows a structure in which a contact layer 9 of the ridge waveguide structure 200 is further cut so that the current flow is interrupted. In addition, a step is formed between the ridge protective layers 300 formed at both sides.

As described in the above-mentioned respective embodiments, according to the present invention, it is possible to provide a high quality semiconductor optical device. As a result, the semiconductor optical device of the present invention can be used for a direct modulation type semiconductor laser, EA modulation integrated laser, and the like, which are superior in wavelength controllability, temperature characteristics.

What is claimed is:

1. A semiconductor optical device, comprising:
a plurality of layers laminated on a semiconductor substrate, wherein a groove is formed as deep as a preset first layer among the plurality of layers, by dry etching and by wet etching after the dry etching;
a spacer layer formed on an upper surface of a second layer located on an upper surface of the plurality of layers; and
a damage receptor layer formed on an upper surface of the spacer layer.

2. A semiconductor optical device according to claim 1, wherein the spacer layer is made of a material which can be selectively etched with respect to the second layer.

3. A semiconductor optical device according to claim 1, wherein:
the spacer layer is made of a material having a small selective ratio with respect to a third layer formed in contact with the upper surface of the first layer,
the damage receptor layer is made of a material having a large selective ratio with respect to the third layer.

4. A semiconductor optical device according to claim 1, wherein the damage receptor layer serves to prevent formation of a damaged layer in the second layer caused by the dry etching.

5. A semiconductor optical device according to claim 1, wherein the spacer layer has a film thickness of 100 nm or more and 3 μm or less.

6. A semiconductor optical device according to claim 1, further comprising at least: a first clad layer, an active layer, a second clad layer, and a contact layer, formed on the semiconductor substrate, wherein:
the first layer is in contact with an undersurface of the second clad layer;
the second layer comprises the contact layer; and
a plurality of grooves is formed so that a ridge waveguide structure is formed between the plurality of grooves.

7. A method of manufacturing a semiconductor optical device, comprising:
a first step of laminating a plurality of layers on a semiconductor substrate, forming a spacer layer on an upper surface of a second layer located on an upper surface of the plurality of layers, and forming a damage receptor layer on the spacer layer;
a second step of forming a plurality of grooves as deep as a preset first layer among the plurality of layers by dry etching and by wet etching after the dry etching, and forming a ridge-type three-dimensional structure between the plurality of grooves;
a third step of forming a protective film on a surface;
a fourth step of exposing the space layer and the damage receptor layer by dry etching the protective film on an upper surface of the three-dimensional structure; and
a fifth step of removing the spacer layer and the damage receptor layer by wet etching.

8. A method of manufacturing a semiconductor optical device according to claim 7, wherein the spacer layer formed in the first step is made of a material which can be selectively etched with respect to the second layer.

9. A method of manufacturing a semiconductor optical device according to claim 7, wherein:
the spacer layer formed in the first step is made of a material having a small selective ratio with respect to a third layer formed in contact with an upper surface of the first layer; and
the damage receptor layer formed in the first step is made of a material having a large selective ratio with respect to the third layer.

10. A method of manufacturing a semiconductor optical device according to claim 7, wherein the damage receptor layer formed in the first step serves to prevent formation of a damaged layer in the second layer, by the dry etching.

11. A method of manufacturing a semiconductor optical device according to claim 7, wherein the spacer layer formed in the first step has a film thickness of 100 nm or more and 3 μm or less.

12. A method of manufacturing a semiconductor optical device according to claim 7, wherein:
the first step comprises: laminating at least a first clad layer, an active layer, a second clad layer, and a contact layer on the semiconductor substrate, and forming the spacer layer and the damage receptor layer on an upper surface of the contact layer; and
the second step comprises forming a plurality of grooves as deep as a layer in contact with an undersurface of the second clad layer and forming a ridge waveguide structure between the plurality of grooves.
